(19) United States
(12) Patent Application Publication
(10) Pub. No.: US 2013/0095665 A1
(43) Pub. Date: Apr. 18, 2013

(54) SYSTEMS AND METHODS FOR PROCESSING SUBSTRATES

(71) Applicant: TES CO. LTD., Yongin (KR)

(72) Inventors: Dong-Duk Lee, Seongnam (KR); U-Young Lee, Seoul (KR); Sang-Sun Lee, Suwon (KR)

(73) Assignee: TES CO. LTD., Yongin (KR)

(21) Appl. No.: 13/689,364

(22) Filed: Nov. 29, 2012

Related U.S. Application Data
(63) Continuation of application No. PCT/KR2012/006240, filed on Aug. 6, 2012.

(30) Foreign Application Priority Data
Oct. 13, 2011 (KR) 10-2011-0104667

(51) Int. Cl. H01L 21/465

(52) U.S. Cl. CPC H01L 21/465
USPC 438/706; 156/345.1; 156/345.31; 156/345.54; 156/345.51

(57) ABSTRACT

A substrate processing system comprises a first processing module in which a process gas is supplied to a substrate to etch a silicon oxide layer formed on the substrate and a second processing module in which an activated oxygen gas is supplied to the substrate. With the system and a method using the same, the silicon oxide layer can be etched and a condensation layer and/or fumes and/or photoresist residues can be removed in a cost-effective way.

### CROSS-REFERENCE TO RELATED APPLICATION

This application is a continuation of International Application No. PCT/KR2012/006240 filed on Aug. 6, 2012, which claims priority to Korean Application No. 10-2011-0104667 filed on Oct. 13, 2011, which applications are incorporated herein by reference.

### BACKGROUND

1. Field of the Invention

The present disclosure generally relates to systems and methods for processing a substrate, which can etch a silicon oxide layer formed on the substrate and remove a condensation layer and/or fumes and/or photoresist residues from the substrate after the etching process in a cost-effective way.

2. Discussion of Related Art

High demand for integration density of semiconductor devices increases the importance of a technique for isolating neighboring electrical devices. A shallow trench isolation (STI) method, which is an isolation technique applied to a semiconductor process, includes forming a trench in a semiconductor substrate to define an active region and filling the inside of the trench with an insulating material to form an isolation layer.

FIG. 1 is a cross-sectional view illustrating a conventional method of forming an isolation layer. Referring to FIG. 1, a pad oxide layer and a nitride layer are sequentially formed on a semiconductor substrate 10. A photoresist pattern (not shown) is formed on the nitride layer, and the nitride layer is patterned using the photoresist pattern to form a nitride layer pattern 30. The pad oxide layer and the semiconductor substrate are etched using the nitride layer pattern 30 as an etch mask, thereby forming a pad oxide layer pattern 20 and a trench 40 defining an active region of the semiconductor substrate 10.

In a subsequent process, the photoresist pattern is removed using an ashing process, and etching byproducts are removed using a wet cleaning process. Thereafter, the inside of the trench 40 is filled with an insulating material, and the nitride layer pattern 30 and the pad oxide layer pattern 20 are then removed, thereby completing formation of an isolation layer.

However, when an underlying layer includes a relatively soft oxide layer, such as a phosphor-doped silicate glass (PSG) layer, a boron phosphorus silicate glass (BPSG) layer, or a spin on dielectric (SOD) layer, damage may be caused to the underlying layer (i.e., the underlying layer may be excessively etched) by a cleaning solution during the wet cleaning process.

To solve the above-described problem associated with the wet cleaning process, a dry cleaning process using hydrogen fluoride (HF) gas has been proposed as an alternative process (e.g., Korean Patent Application Publication No. 10-2008-0039809). However, when the dry cleaning process is applied, a delay in process time occurs due to the transfer of a substrate between an etching apparatus configured to form a pattern and a dry cleaning apparatus used after an etching process, which results in formation of fumes in the pattern.

FIG. 2 is a schematic top view showing a state where fumes 50 are formed within a trench 40 of a semiconductor substrate 10 when the semiconductor substrate 10 is exposed to the atmosphere while being transferred to a dry cleaning apparatus after the trench 40 is formed in an etching apparatus.

As shown in FIG. 2, the fumes 50 are formed on the entire surface of the semiconductor substrate 10. Analysis of the fumes using x-ray photoelectron spectrometry (XPS) or Auger electron spectroscopy (AES) shows that fumes contain SiO₂. The fumes 50 are formed as a solid hydrate by a reaction of halogen elements (e.g., fluorine (F), chloride (Cl), or bromine (Br)) contained in an etch gas used for an etching process, which remain within the trench 40, with atmospheric moisture during exposure to the atmosphere. The fumes 50 become problematic not only in an STI process but also in all processes adopting a post-patterning dry cleaning process, for example, a process of forming gate lines and bit lines.

As described above, while a wet cleaning process, which involves a hydrolysis reaction with a wet cleaning solution, such as a buffered oxide etchant (BOE) or hydrogen peroxide (H₂O₂), does not cause fumes to be formed, it causes damage to an underlying layer. Conversely, a dry cleaning process causes formation of fumes.

Accordingly, a demand for a new substrate processing system and method still exists.

### SUMMARY OF THE INVENTION

The present disclosure provides a substrate processing system and method to prevent damage to an underlying layer and efficiently remove both etching byproducts and fumes.

One aspect of the present invention provides a substrate processing system. The system comprises a first processing module and a second processing module. The first processing module is configured to provide a process gas containing hydrogen fluoride (HF) to a substrate on which a silicon oxide layer is formed, thereby etching the silicon oxide layer formed on the substrate. The second processing module is configured to provide activated oxygen gas to the substrate.

In some embodiments, the system may further comprise a cassette module, a first transfer module, a second transfer module, and a loadlock module. The cassette module is configured to receive the substrate. The first transfer module is connected to the cassette module and is configured to transfer the substrate to or from the cassette module. The second transfer module is connected to the first processing module and the second processing module and is configured to transfer the substrate to/from the first processing module, the second processing module, or both. The loadlock module is connected to the first and second transfer modules and is configured to transfer the substrate from/to the first transfer module to/from the second transfer module.

In some embodiments, the process gas may further contain ammonia (NH₃) gas and an inert gas. Non-limiting examples of the inert gas include N₂, Ar, and He.

In some embodiments, the process gas may further contain isopropyl alcohol (IPA).

In some embodiments, the first processing module may comprise a chamber connected to the second transfer module, a susceptor provided in the chamber, and a gas supplier provided in the chamber. The susceptor is movable upwardly or downwardly and configured to allow the substrate to be mounted thereon. The gas supplier is configured to provide the process gas to the substrate mounted on the susceptor.

In some embodiments, the second processing module may comprise a chamber connected to the second transfer module, a susceptor provided in the chamber and configured to allow the substrate to be mounted thereon, and a gas supplier provided in the chamber for providing the activated oxygen gas to the substrate mounted on the susceptor, in which the gas supplier receives the activated oxygen from a remote plasma source.

Another aspect of the present invention provides a method of processing a substrate. The method comprises a first processing step of providing a process gas containing hydrogen fluoride (HF) to a substrate on which a silicon oxide layer is formed, thereby etching the silicon oxide layer formed on the substrate, and a second processing step of supplying activated oxygen gas to the substrate.

In some embodiments, the method may further comprise a preliminary process of supplying activated oxygen gas before the first processing step.

In some embodiments, in the first processing step, the process gas may further contain ammonia (NH₃) gas and an inert gas. Non-limiting examples of the inert gas include N₂, Ar, and He.

In some embodiments, in the first processing step, the process gas may further contain isopropyl alcohol (IPA).

In some embodiments, in the second processing step, the activated oxygen gas may be provided with an inert gas.

In some embodiments, the process gas may be provided to the substrate after the substrate is heated to a temperature suitable for a cleaning or etching reaction.

In some embodiments, the first processing step may comprise a first annealing process for heating the substrate to a predetermined temperature. Preferably, the substrate is heated to a temperature ranging from about 80° C. to about 200° C. in the first annealing process.

In some embodiments, the second processing step may comprise a second annealing process for heating the substrate to a predetermined temperature. Preferably, the substrate is heated to a temperature ranging from about 100° C. to about 400° C. in the second annealing process. In some modified embodiments, the activated oxygen gas may be provided to the substrate (i) after the substrate is heated by the second annealing process, (ii) while the substrate is being heated by the second annealing process, or (iii) before the substrate is heated by the second annealing process.

In some embodiments, the method may further comprise an annealing process in the first processing step, in the second processing step, or in the first and second processing steps. By the annealing process(es), at least one of a condensation layer that is formed by reaction of the silicon oxide layer with the process gas in the first processing step, photoresist residues that remain in the first processing step, and fumes that are formed in the first processing step can be removed.

According to the present invention as described above, a silicone oxide layer on a substrate can be etched efficiently and a condensation layer and/or fumes and/or photoresist residues can be removed from the etched substrate efficiently.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a cross-sectional view illustrating a conventional method of forming an isolation layer.

FIG. 2 is a schematic top view showing a state where fumes are formed within a trench of a semiconductor substrate when the semiconductor substrate is exposed to the atmosphere before being subjected to a dry process.

FIG. 3 is a schematic diagram of a substrate processing system according to an exemplary embodiment.

FIG. 4 is a schematic diagram of a first processing module of the system of FIG. 3.

FIG. 5 is a schematic diagram of a second processing module of the system of FIG. 3.

FIG. 6 is a flowchart illustrating a method of processing a substrate according to an exemplary embodiment.

FIGS. 7 through 11 are flowcharts illustrating methods of processing a substrate according to other exemplary embodiments.

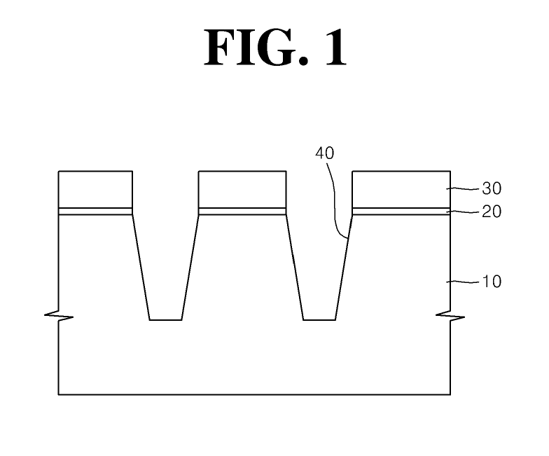

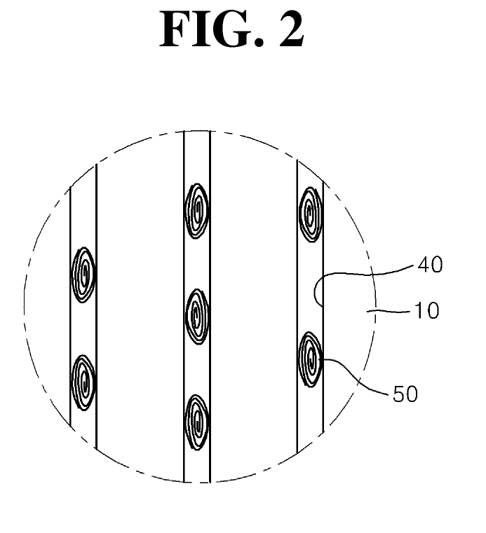

### DETAILED DESCRIPTION OF EXEMPLARY EMBODIMENTS

Systems and methods for processing a substrate according the present invention will now be described hereinafter with reference to the accompanying drawings, in which exemplary embodiments of the present invention are shown.

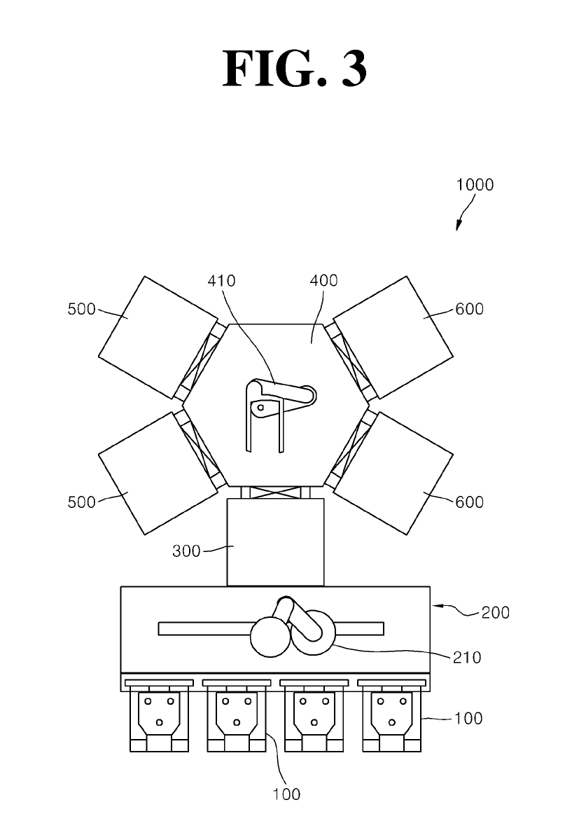

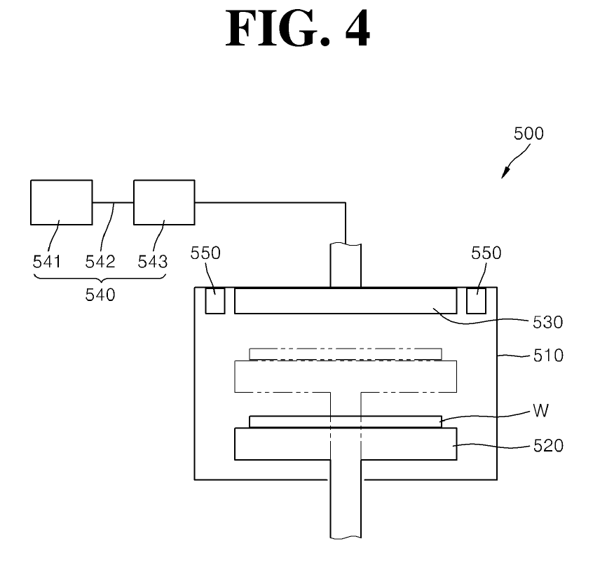

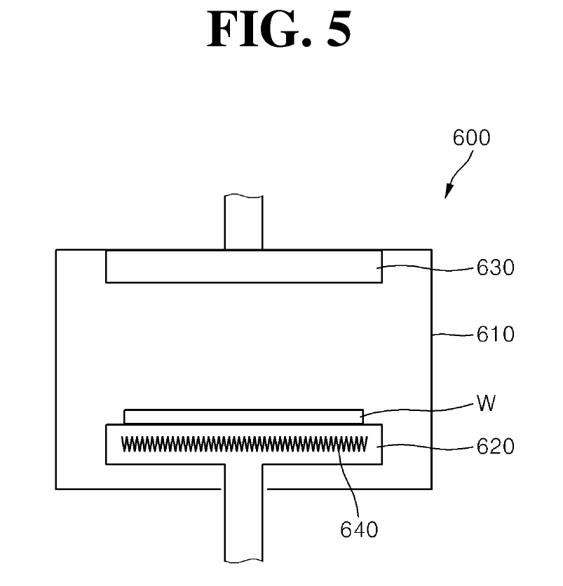

Hereinafter, systems of processing a substrate according to embodiments of the present invention will be described, with reference to FIGS. 3 to 5. FIG. 3 is a schematic diagram of a substrate processing system according to an exemplary embodiment. FIG. 4 is a schematic diagram of a first processing module of the system of FIG. 3. FIG. 5 is a schematic diagram of a second processing module of the system of FIG. 3.

Referring to FIGS. 3 through 5, the substrate processing system 1000 according to the embodiment includes cassette modules 100, a first transfer module 200, a loadlock module 300, a second transfer module 400, first processing modules 500, and second processing modules 600.

Each of the cassette modules 100 is configured to receive at least one substrate that is to be processed and/or at least one substrate that has been processed. For example, as shown in FIG. 3, four cassette modules can be disposed in a row. The first transfer module 200 is configured to transfer the substrate to or from the cassette module(s) 100. The first transfer module 200 can be connected to at least one cassette module 100. For example, as shown in FIG. 3, the first transfer module 200 is connected to the four cassette modules and includes at least one transfer robot 210. The transfer robot 210 is capable of moving along a direction in which the four cassette modules 100 are disposed and transferring the substrates between the loadlock module 300 and the cassette modules 100.

The loadlock module 300 is connected to the first and second transfer modules and configured to transfer the substrate from/to the first transfer module to/from the second transfer module.

The second transfer module 400 is configured to transfer the substrates to (or from) the first processing module 500, the second processing module 600, or both. The second transfer module 400 is connected to the loadlock module 300, the first processing module 500, and the second processing module 600. At least one transfer robot 410 configured to transfer the substrates is provided inside the second transfer module 400. In this case, for example, the transfer robot 410 may include a dual-type transfer robot having two transfer arms.

The first processing module 500 is configured to clean (or etch) the substrate by a dry process. The system may include at least one first processing module 500. For example, the system shown in FIG. 3 includes two first processing modules 500 that are connected to the second transfer module 400.

For example, the first processing module 500 may include a chamber 510, a susceptor 520, and a gas supplier 530, as shown in FIG. 4. The chamber 510 is installed to communicate with the second transfer module 400 through a gate that can be opened and closed. The susceptor 520 is provided in the chamber 510. The susceptor 520 can be moved upwardly or downwardly and is configured to allow the substrate (W) to be mounted thereon. The susceptor 520 may be provided with a heat exchanger for controlling the temperature of the substrate (W). The gas supplier 530 is provided in the chamber 510 for providing a process gas in a predetermined direction to the substrate (W) mounted on the susceptor 520. Examples of the gas supplier 530 include, but not limited to, a gas nozzle, a gas spray plate, and a shower head.

The gas supplier 530 of the first processing module 500 is connected to a gas supply system 540. For example, the gas supply system 540 may include a gas source 541 (e.g., a gas cylinder or canister configured to contain a liquid), a gas supply line 542 directly or indirectly connected to the gas source 541 and the gas supplier 530, and a mass flow controller (MFC) 543 installed on the gas supply line 542.

In some embodiments, the process gas supplied from the gas supply system 540 can be mixed inside the gas supplier 530. In some other embodiments, the process gas supplied from the gas supply system 540 can be mixed in the chamber 510 after passing the gas supplier 530. In some other embodiments, the gas supplier 530 may have one gas flow paths formed therein. Alternatively, it may have two or more independent gas flow paths formed therein. The number and shape of the gas supplier 530 can be designed appropriately depending on design and/or technical needs. The gas supplier 530 can be placed in an appropriate position such that the process gas can be supplied in a predetermined direction (e.g., upwardly, downwardly, horizontally, etc.).

The system may further include a heat supplier 550. As a non-limiting example, a halogen lamp 550 may be disposed at a top end portion of the chamber 510. Also, the heat supplier may include a resistance heater in the susceptor.

The process gas contains hydrogen fluoride (HF). Preferably, the process gas may further contain NH₃. In some embodiments, respective components of the process gas are supplied by respective gas supply systems 540. In some other embodiments, all components of the process gas are supplied by a single gas supply system 540.

The pressure of the chamber 510 of the first processing module 500 can be set or controlled to be set to a predetermined pressure or a predetermined pressure range. Also, the temperature of the chamber 510, the susceptor 520, and the gas supplier 530 can be set or controlled to be set to a predetermined temperature or a predetermined temperature range that is suitable for a cleaning or etching reaction of the process gas and/or does not allow the process gas to be condensed. In some embodiments, the inner pressure of the chamber 510 may be maintained at about 10 mTorr to about 150 Torr, the temperature of the susceptor 520 may be maintained at about 20° C. to about 70° C., and the temperature of the gas supplier 530 may be maintained at about 50° C. to about 150° C. The pressure and temperature can be set or controlled to be set to a predetermined value using methods known in the art (e.g., providing a heater, providing a fluid path for heat exchange), detailed description of which is omitted.

In some embodiments, as described above, components of the process gas (e.g., HF and NH₃) can be introduced to the chamber 510 through the gas supplier 530. The components, as described above, can be mixed inside the gas supplier 530 or in the chamber 510. For example, the process gas including HF and NH3 can be separately introduced into the chamber, and be mixed in the chamber 510. The process gas then can chemically react with the silicon oxide layer on the substrate (W). The chemical reaction causes the silicon oxide layer to become a condensation layer.

Afterwards, the susceptor 520 is moved toward the heat supplier 550 (e.g., halogen lamp) as shown in the dotted line of FIG. 4. The substrate (W) is heated to a temperature of about 80° C. to about 200° C. (preferably, about 100° C. to about 150° C.), thereby removing the condensation layer (first annealing process).

Meanwhile, the process gas may further contain at least one inert gas selected from nitrogen (N₂) gas, argon (Ar) gas, and helium (He) gas as a carrier gas. Also, the process gas may further contain isopropyl alcohol (IPA). If IPA is in a liquid state, it can be introduced by bubbling or vaporizing.

The second processing module 600 is configured to remove photoresist residues that may remain on the substrate after a shallow trench isolation (STI) process and/or fumes that may be formed as a solid hydrate by the reaction of atmospheric moisture (or impurities existing in silicon oxide) with halogen elements (e.g., fluoride (F), chloride (Cl), or bromine (Br)) contained in an etch gas, which remain within a trench 40 of the substrate during an etching process for forming a pattern in the substrate. The system may include at least one second processing module 600. For example, the system shown in FIG. 3 includes two second processing modules 600 that are connected to the second transfer module 400

For example, the second processing module 600 may include a chamber 610, a susceptor 620, and a gas supplier 630, as shown in FIG. 5. The chamber 610 is installed to communicate with the second transfer module 400 through a gate that can be opened and closed. The susceptor 620 is installed within the chamber 610. The substrate (W) is to be mounted on the susceptor 620. A gas supplier 630 is installed within the chamber 610 and configured to supply an activated oxygen gas (O₂ radical) to the substrate (W). The gas supplier 630 is connected to an oxygen remote plasma source (oxygen RPS). Preferably, the gas supplier 630 may further supply at least one of N₂ gas, Ar gas, and He gas.

The second processing module 600 may further comprise a heat supplier 640 for heating the substrate. As a non-limiting example, a resistance heater 640 may be disposed in the susceptor. Also, the heat supplier may include a halogen lamp. The heat supplier functions to heat the substrate to a process temperature of about 100° C. to about 400° C. (preferably, about 200° C. to about 300° C., and more preferably, about 220° C. to about 270° C.) (second annealing process).

In addition, the activated oxygen gas supplied to the substrate heated to the process temperature can react with and remove fumes formed on the substrate. Also, the inert gas supplied with the activated oxygen can prevent recombination of radicals, that is, recombination of dissociated oxygen atoms into oxygen molecules, thereby improving fumes removal efficiency.

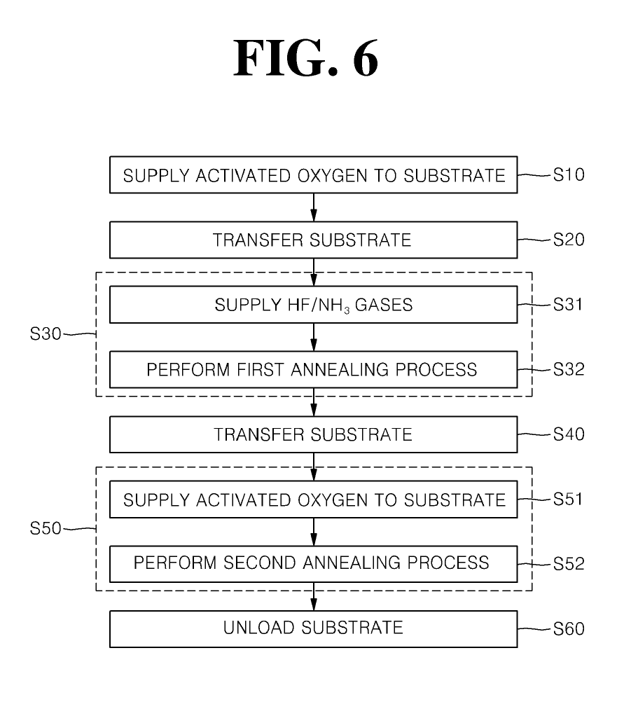

Hereinafter, methods of processing a substrate using the substrate processing system according to embodiments of the present invention will be described with reference to FIG. 6.

Referring to FIG. 6, a substrate to be processed is contained in the cassette module 100. The substrate to be processed may be a substrate patterned by etching using an etch gas containing halogen elements, such as F, Cl, and Br. The substrate may be transferred to the first transfer module 200, the loadlock module 300, and the second transfer module 400 sequentially, after which the substrate may be transferred to the first processing module 500 or the second processing module 600.

A preliminary process (S10) is performed in the second processing module 600. An activated oxygen gas can be provided to the substrate (i) after the substrate is heated to a temperature of about 100° C. to about 400° C. (preferably, about 200° C. to about 300° C., and more preferably, about 220° C. to about 270° C.), (ii) while the substrate is being heated to the temperature, or (iii) before the substrate is heated to the temperature. In the preliminary process, photoresist residues that may remain on the substrate as well as fumes formed in the previous etch process, can be removed. Afterwards, the substrate is transferred through the second transfer module 400 to the first processing module 500 (S20).

A first process (S30) is performed in the first processing module 500. A process gas (e.g., HF and NH₃) can be supplied to the substrate while the substrate is being maintained to a temperature (about 20° C. to about 70° C.) suitable for a cleaning or etching reaction (S31). The process gas chemically reacts with a silicon oxide layer on the substrate to form a condensation layer. Thereafter, after a susceptor is moved upwardly, the substrate is heated to a temperature of about 80° C. to about 200° C. (preferably, about 100° C. to about 150° C.) (i.e., first annealing process) (S32) by the heat supplier 550, thereby removing the condensation layer. Afterwards, the substrate is transferred to the second processing module 600.

A second process (S50) is performed in the second processing module 600. An activated oxygen gas can be provided to the substrate (i) after the substrate is heated to a temperature of about 100° C. to about 400° C. (preferably, about 200° C. to about 300° C., and more preferably, about 220° C. to about 270° C.), (ii) while the substrate is being heated to the temperature, or (iii) before the substrate is heated to the temperature (second annealing process). The activated oxygen gas reacts with fumes formed on the substrate to remove the fumes. In some embodiments, the activated oxygen gas can be supplied with an inert gas such as N2, Ar, or He, which can prevent recombination of oxygen atoms into oxygen molecules, thereby more efficiently removing the fumes.

The activated oxygen gas and oxygen remote plasma source described above can be replaced with an activated hydrogen gas and H2 remote plasma source respectively.

Subsequently, the substrate is transferred from the second processing module 600 to the cassette module 100 (S60), being ready to be moved to a subsequent process.

According to the above-described embodiments of the present invention, a silicon oxide layer on the substrate can be etched efficiently by a dry process and a condensation layer and/or fumes and/or photoresist residues can be removed from the substrate efficiently by a dry process without causing problems associated with a conventional wet cleaning process (e.g., damage to an underlying layer formed of spin on dielectric (SOD) or boron phosphorus silicate glass (BPSG)).

In particular, when a silicon oxide layer was removed using a dry etching process, fumes were formed on the substrate within about 1 to 3 hours after the silicon oxide layer was removed. On the other hand, when a silicon oxide layer was removed using a dry etching process and an activated oxygen gas was supplied to the substrate after the silicon oxide layer was removed, fumes that had existed were removed and additional fumes were not formed even 24 hours after the activated oxygen gas was supplied.

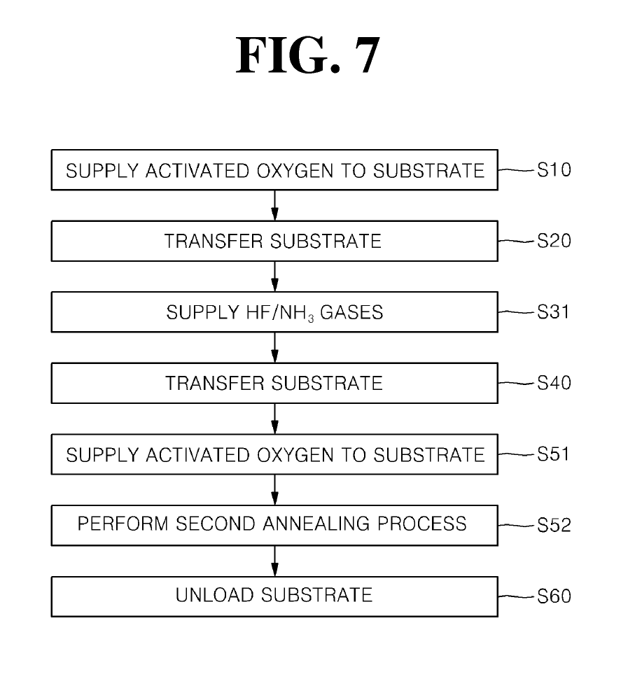

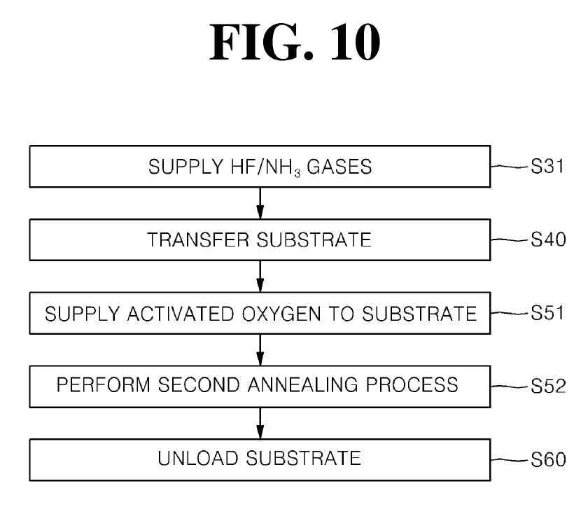

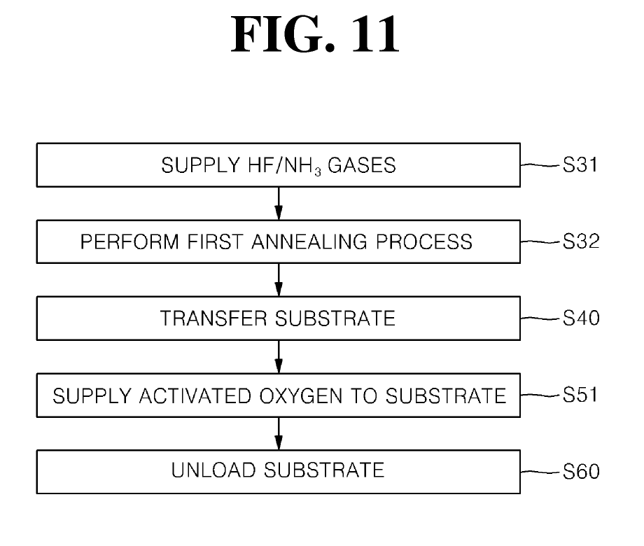

Methods of processing a substrate according to other embodiments will be described with reference to FIGS. 7 to 11.

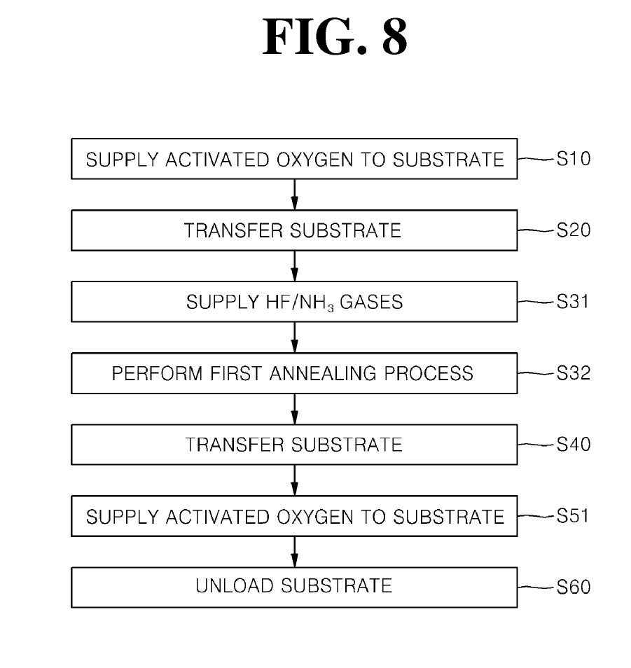

Either the first annealing process or the second annealing process can be omitted from the method described with reference to FIG. 6. FIG. 7 shows a method of processing a substrate in which the first annealing process is omitted from the method described with reference to FIG. 6. As the method described in FIG. 7 is identical or substantially identical to the one described with reference to FIG. 6 except that it does not have the first annealing process, detailed description thereof is omitted. FIG. 8 shows a method of processing a substrate in which the second annealing process is omitted from the method described with reference to FIG. 6. As the method described in FIG. 8 is identical or substantially identical to the one described with reference to FIG. 6 except that it does not have the second annealing process, detailed description thereof is omitted.

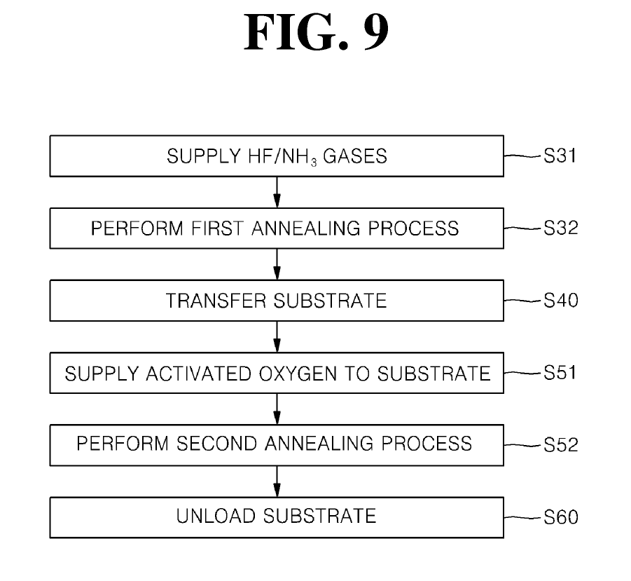

Further, the preliminary process can be omitted from the methods described with reference to FIGS. 6 to 8. FIGS. 9 to 11 show methods of processing a substrate in which the preliminary process is omitted from the methods described with reference to FIGS. 6 to 8, respectively. As the methods described in FIGS. 9 to 11 are identical or substantially identical to the ones described with reference to FIGS. 6 to 8 except that they do not have the preliminary process, detailed description thereof is omitted.

With the systems and methods according to the embodiments of the present invention, a silicon oxide layer on a substrate can be etched and a condensation layer and/or fumes and/or photoresist residues can be removed from the substrate after the etching process in a cost-effective way.

While the disclosure has been shown and described with reference to m certain exemplary embodiments thereof, it will be understood by those skilled in the art that various changes in form and details may be made therein without departing from the spirit and scope of the disclosure as defined by the appended claims.

What is claimed is:

1. A substrate processing system comprising:
a first processing module configured to provide a process gas containing hydrogen fluoride (HF) to a substrate on which a silicon oxide layer is formed, thereby etching the silicon oxide layer formed on the substrate; and
a second processing module configured to provide activated oxygen gas to the substrate.

2. The system of claim 1, further comprising:
a cassette module configured to receive the substrate;
a first transfer module connected to the cassette module and configured to transfer the substrate to or from the cassette module;
a second transfer module connected to the first processing module and the second processing module and configured to transfer the substrate to/from the first processing module, the second processing module, or both; and
a loadlock module connected to the first and second transfer modules and configured to transfer the substrate from/to the first transfer module to/from the second transfer module.

3. The system of claim 1, wherein the process gas further contains ammonia (NH₃) gas and an inert gas.

4. The system of claim 3, wherein the inert gas comprises at least one selected from the group consisting of N₂, Ar, and He.

5. The system of claim 1, wherein the process gas further contains isopropyl alcohol (IPA).

6. The system of claim 1, wherein the first processing module comprises:
a chamber connected to the second transfer module;
a susceptor provided in the chamber, being able to move upwardly or downwardly, and configured to allow the substrate to be mounted thereon; and
a gas supplier provided in the chamber for providing the process gas to the substrate mounted on the susceptor.

7. The system of claim 1, wherein the second processing module comprises:
a chamber connected to the second transfer module;
a susceptor provided in the chamber and configured to allow the substrate to be mounted thereon; and
a gas supplier provided in the chamber for providing the activated oxygen gas to the substrate mounted on the susceptor,
wherein the gas supplier receives the activated oxygen from a remote plasma source.

8. A method of processing a substrate, comprising:
a first processing step of providing a process gas containing hydrogen fluoride (HF) to a substrate on which a silicon oxide layer is formed, thereby etching the silicon oxide layer formed on the substrate; and
a second processing step of supplying activated oxygen gas to the substrate.

9. The method of claim 8, further comprising a preliminary process of supplying activated oxygen gas before the first processing step.

10. The method of claim 8, wherein, in the first processing step, the process gas further contains ammonia (NH₃) gas and an inert gas.

11. The method of claim 8, wherein the inert gas comprises at least one selected from the group consisting of N₂, Ar, and He.

12. The method of claim 8, wherein, in the first processing step, the process gas further contains isopropyl alcohol (IPA).

13. The method of claim 8, wherein, in the second processing step, the activated oxygen gas is provided with an inert gas.

14. The method of claim 8, wherein the process gas is provided to the substrate while the substrate is being maintained to a temperature suitable for a cleaning or etching reaction.

15. The method of claim 8, wherein the first processing step comprises a first annealing process for heating the substrate to a predetermined temperature after the process gas is provided to the substrate.

16. The method of claim 8, wherein the second processing step comprises a second annealing process for heating the substrate to a predetermined temperature.

17. The method of claim 16, wherein the activated oxygen gas is provided to the substrate (i) after the substrate is heated by the second annealing process, (ii) while the substrate is being heated by the second annealing process, or (iii) before the substrate is heated by the second annealing process.

18. The method of claim 8, further comprising an annealing process in the first processing step, the second processing step, or both, thereby removing at least one of a condensation layer that is formed by reaction of the silicon oxide layer with the process gas in the first processing step, photoresist residues that remain in the first processing step, and fumes that are formed in the first processing step.

19. The method of claim 9, wherein in the preliminary process, the activated oxygen gas is provided to the substrate (i) after the substrate is heated, (ii) while the substrate is being heated, or (iii) before the substrate is heated.
